(19) United States
(12) Patent Application Publication
(10) Pub. No.: US 2026/0255624 A1
(43) Pub. Date: Aug. 27, 2026

(54) SEMICONDUCTOR POWER DEVICE AND MANUFACTURING METHOD THEREOF

(71) Applicant: National Tsing Hua University, Hsinchu City (TW)

(72) Inventor: King Yuen Wong, Hsinchu City (TW)

(73) Assignee: National Tsing Hua University, Hsinchu City (TW)

(21) Appl. No.: 19/082,204

(22) Filed: Mar. 18, 2025

(30) Foreign Application Priority Data
Feb. 27, 2025 (TW) 114107301

(51) Int. Cl. H10D 30/47; H10D 30/01; H10D 62/824; H10D 64/27; H10D 64/66

(52) U.S. Cl. CPC H10D 30/475; H10D 30/015; H10D 62/824; H10D 64/513; H10D 64/518; H10D 64/666; H10D 64/667

(57) ABSTRACT

A semiconductor power device and a manufacturing method thereof are provided. The semiconductor power device includes a substrate, a buffer layer disposed on the substrate, a nitride channel layer disposed on the buffer layer, a source and a drain disposed on the nitride channel layer, a barrier layer disposed on the nitride channel layer between the source and the drain, a first etching stop layer disposed on the barrier layer and the source and the drain, a first passivation layer disposed on the first etching stop layer, a second etching stop layer disposed on the first passivation layer, a second passivation layer disposed on the second etching stop layer, a gate structure disposed in the second passivation layer, the second etching stop layer, and the first passivation layer, a spacer disposed between the gate structure and the second passivation layer and the second etching stop layer, and a field plate structure disposed in the second passivation layer. A two-dimensional electron gas is located in the nitride channel layer between the source and the drain, and is adjacent to an interface between the nitride channel layer and the barrier layer.

### CROSS-REFERENCE TO RELATED APPLICATION

This application claims the priority benefit of Taiwan application no. 114107301, filed on Feb. 27, 2025. The entirety of the above-mentioned patent application is hereby incorporated by reference herein and made a part of this specification.

### BACKGROUND

### Technical Field

The disclosure relates to a semiconductor device, and particularly relates to a semiconductor power device.

### Description of Related Art

In recent years, to meet the demand for high-frequency semiconductor devices, semiconductor power devices have developed into group III-V semiconductor power devices, such as GaN HEMT devices. Generally, in GaN HEMT devices, due to spontaneous polarization and piezoelectric polarization effects at the interface between the AlGaN layer serving as a barrier layer and the GaN layer serving as a channel layer, a two-dimensional electron gas (2DEG) is formed in the AlGaN layer below the aforementioned interface. Through factors such as the high electron mobility of electrons themselves, the high concentration of electrons in the two-dimensional electron gas, and the low sheet resistance of GaN, group III-V semiconductor materials are suitable for high-frequency applications.

### SUMMARY

The disclosure provides a semiconductor power device and a manufacturing method thereof. The semiconductor power device includes a power transistor and a field plate, and a gate structure of the power transistor and the field plate are formed in a stacked structure constituted by multiple etching stop layers and multiple passivation layers.

A semiconductor power device of the disclosure includes a substrate, a buffer layer, a nitride channel layer, a source and a drain, a barrier layer, a first etching stop layer, a first passivation layer, a second etching stop layer, a second passivation layer, a gate structure, a spacer, and a field plate structure. The buffer layer is disposed on the substrate. The nitride channel layer is disposed on the buffer layer. The source and the drain are disposed on the nitride channel layer. The barrier layer is disposed on the nitride channel layer between the source and the drain. The first etching stop layer is disposed on the barrier layer and the source and the drain. The first passivation layer is disposed on the first etching stop layer. The second etching stop layer is disposed on the first passivation layer. The second passivation layer is disposed on the second etching stop layer. The gate structure is disposed in the second passivation layer, the second etching stop layer, and the first passivation layer. The spacer is disposed between the gate structure and the second passivation layer and the second etching stop layer. The field plate structure is disposed in the second passivation layer. A two-dimensional electron gas is located in the nitride channel layer between the source and the drain, and is adjacent to an interface between the nitride channel layer and the barrier layer.

In an embodiment of the semiconductor power device of the disclosure, a thickness of the second etching stop layer is greater than a thickness of the first etching stop layer.

In an embodiment of the semiconductor power device of the disclosure, the gate structure further extends through the barrier layer.

In an embodiment of the semiconductor power device of the disclosure, the two-dimensional electron gas does not exist below the gate structure.

In an embodiment of the semiconductor power device of the disclosure, the field plate structure further extends through the second etching stop layer.

In an embodiment of the semiconductor power device of the disclosure, a third etching stop layer is further included. The third etching stop layer is disposed on the second passivation layer. The gate structure and the field plate structure further extend through the third etching stop layer.

In an embodiment of the semiconductor power device of the disclosure, a thickness of the third etching stop layer is greater than a thickness of the second etching stop layer.

In an embodiment of the semiconductor power device of the disclosure, a bottom portion of the field plate structure is located at the second etching stop layer.

In an embodiment of the semiconductor power device of the disclosure, the gate structure includes a first conductive layer, a dielectric layer, and a second conductive layer. The dielectric layer is disposed on a sidewall and a bottom surface of the first conductive layer. The second conductive layer is disposed between the first conductive layer and the dielectric layer.

In an embodiment of the semiconductor power device of the disclosure, the field plate structure includes the first conductive layer, the dielectric layer, and the second conductive layer. The dielectric layer is disposed on the sidewall and the bottom surface of the first conductive layer. The second conductive layer is disposed between the first conductive layer and the dielectric layer.

In an embodiment of the semiconductor power device of the disclosure, a width of a top portion of the gate structure is greater than a width of a bottom portion of the gate structure.

A manufacturing method of the semiconductor power device of the disclosure includes the following steps. In an embodiment of the manufacturing method of the semiconductor power device of the disclosure, a buffer layer is formed on a substrate. A nitride channel layer is formed on the buffer layer. A source and a drain are formed on the nitride channel layer. A barrier layer is formed on the nitride channel layer between the source and the drain. A first etching stop layer is formed on the barrier layer and the source and the drain. A first passivation layer is formed on the first etching stop layer. A second etching stop layer is formed on the first passivation layer. A second passivation layer is formed on the second etching stop layer. A gate structure is formed in the second passivation layer, the second etching stop layer, and the first passivation layer. A spacer is formed between the gate structure, the second passivation layer, and the second etching stop layer. A field plate structure is formed in the second passivation layer. A two-dimensional electron gas is located in the nitride channel layer between the source and the drain, and is adjacent to an interface between the nitride channel layer and the barrier layer.

In an embodiment of the manufacturing method of the semiconductor power device of the disclosure, the gate structure includes a first conductive layer, a dielectric layer, and a second conductive layer. The dielectric layer is disposed on a sidewall and a bottom surface of the first conductive layer. The second conductive layer is disposed between the first conductive layer and the dielectric layer.

In an embodiment of the manufacturing method of the semiconductor power device of the disclosure, the field plate structure includes the first conductive layer, the dielectric layer, and the second conductive layer. The dielectric layer is disposed on the sidewall and the bottom surface of the first conductive layer. The second conductive layer is disposed between the first conductive layer and the dielectric layer.

In an embodiment of the manufacturing method of the semiconductor power device of the disclosure, the formation method of the gate structure, the spacer, and the field plate structure includes the following steps. In an embodiment of the manufacturing method of the semiconductor power device of the disclosure, after forming the second passivation layer, a third etching stop layer is formed on the second passivation layer. A first etching process is performed to form a first trench in the third etching stop layer, the second passivation layer, and the second etching stop layer. The spacer is formed on a sidewall of the first trench. A second etching process is performed to form a second trench in the third etching stop layer. A third etching process is performed to extend the first trench downward through the first passivation layer, and to extend the second trench downward through the second passivation layer, in which the first trench exposes the first etching stop layer, and the second trench exposes the second etching stop layer. The dielectric layer, the second conductive layer, and the first conductive layer are sequentially formed in the first trench and the second trench.

In an embodiment of the manufacturing method of the semiconductor power device of the disclosure, after performing the third etching process and before forming the dielectric layer, the method further includes removing the third etching stop layer, the first etching stop layer exposed by the first trench, and the second etching stop layer exposed by the second trench.

In an embodiment of the manufacturing method of the semiconductor power device of the disclosure, a thickness of the third etching stop layer is greater than a thickness of the second etching stop layer, and the thickness of the second etching stop layer is greater than a thickness of the first etching stop layer.

In an embodiment of the manufacturing method of the semiconductor power device of the disclosure, the formation method of the first conductive layer includes performing a chemical vapor deposition process.

In an embodiment of the manufacturing method of the semiconductor power device of the disclosure, the formation method of the second conductive layer includes performing an atomic layer deposition process.

In an embodiment of the manufacturing method of the semiconductor power device of the disclosure, a width of a top portion of the gate structure is greater than a width of a bottom portion of the gate structure.

Based on the above, in the semiconductor power device and a manufacturing method thereof of the disclosure, by forming the etching stop layer, the first trench and the second trench with different depths may be formed in the same etching process. In addition, by forming the spacer in the first trench, a width of the region used to accommodate the gate structure of the power transistor in the semiconductor power device may be reduced, and therefore it is advantageous for forming a gate structure with a smaller width. Furthermore, the gate structure and the field plate structure may be constituted of the same material, and may be formed in the same process step.

### BRIEF DESCRIPTION OF THE DRAWINGS

FIG. 1A to FIG. 1G are schematic cross-sectional views of a manufacturing process of a semiconductor power device according to a first embodiment of the disclosure.

FIG. 2 is a schematic cross-sectional view of a semiconductor power device according to a second embodiment of the disclosure.

FIG. 3 is a schematic cross-sectional view of a semiconductor power device according to a third embodiment of the disclosure.

FIG. 4 is a schematic cross-sectional view of a semiconductor power device according to a fourth embodiment of the disclosure.

### DESCRIPTION OF THE EMBODIMENTS

The embodiments are described in detail below with reference to the accompanying drawings, but the embodiments are not intended to limit the scope of the disclosure. In addition, the drawings are for illustrative purposes only and are not drawn to the original dimensions. For the purpose of easy understanding, the same elements in the following description will be denoted by the same reference numerals.

In the text, the terms mentioned in the text, such as “comprising”, “including” and “having” are all open-ended terms, i.e., meaning “including but not limited to”.

When using terms such as “first” and “second” to describe elements, it is only used to distinguish the elements from each other, and does not limit the order or importance of these elements. Therefore, in some cases, the first element can also be called the second element, and the second element can also be called the first element, and this does not deviate from the scope of the disclosure.

In addition, the directional terms mentioned in the text, such as “up”, “down”, etc., are only used to refer to the direction of the drawings, and are not used to limit the disclosure. Therefore, it should be noted that “on” can be used interchangeably with “under”, and when an element such as a layer or film is placed “on” another element, the element can be directly placed on the other element, or there may be an intermediate element disposed therebetween. On the other hand, when an element is described as being placed “directly” on another element, there is no intermediate element between the two.

Additionally, in the text, the range represented by “a value to another value” is a summary expression way to avoid listing all the values in the range one by one in the specification. Therefore, the record of a specific numerical range covers any numerical value within the numerical range, as well as a smaller numerical range defined by any numerical value within the numerical range.

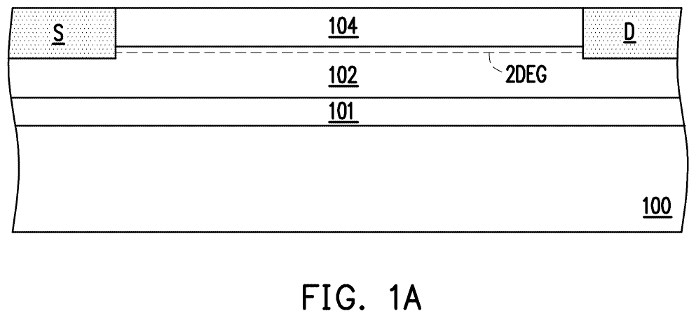

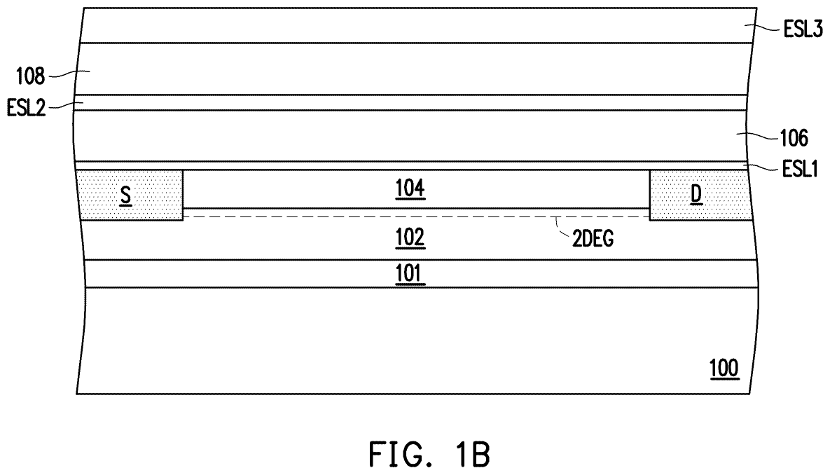

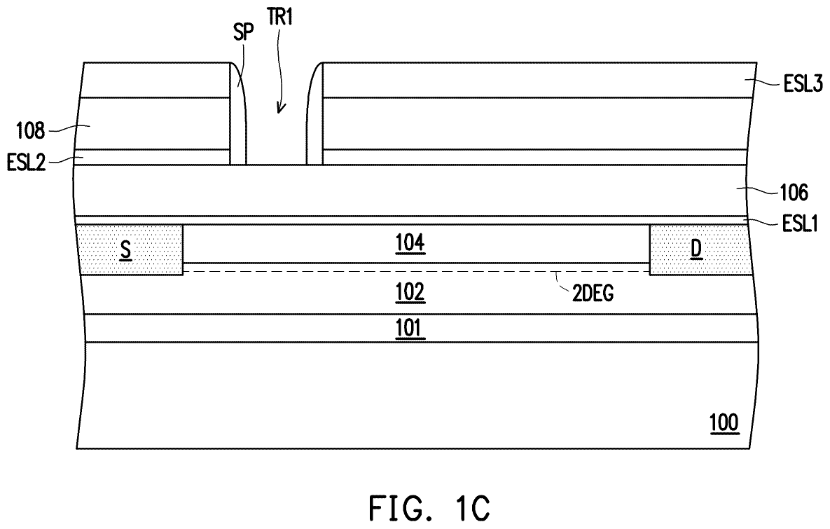

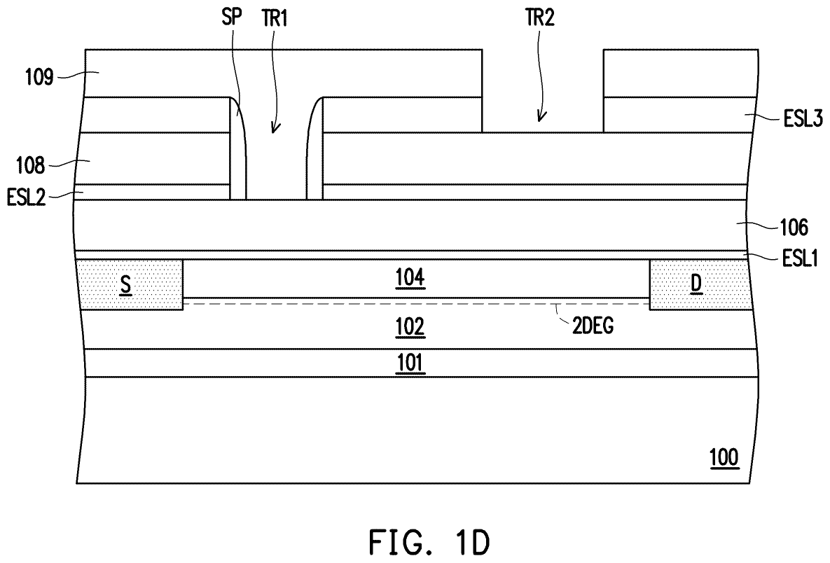

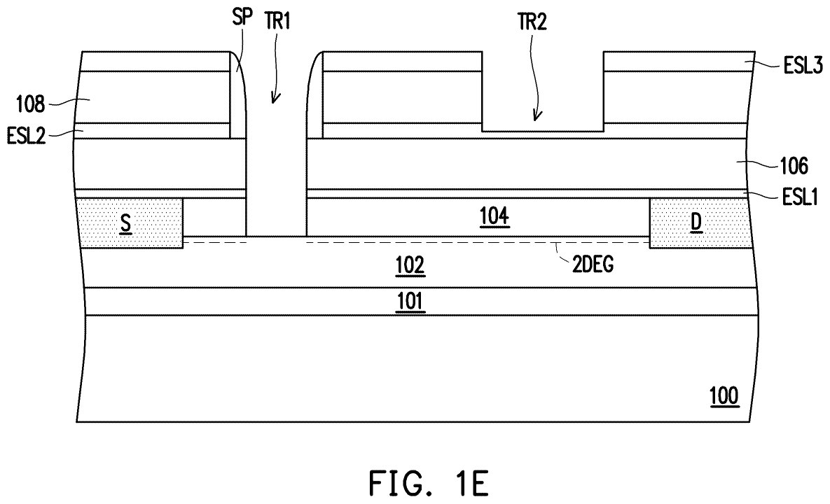

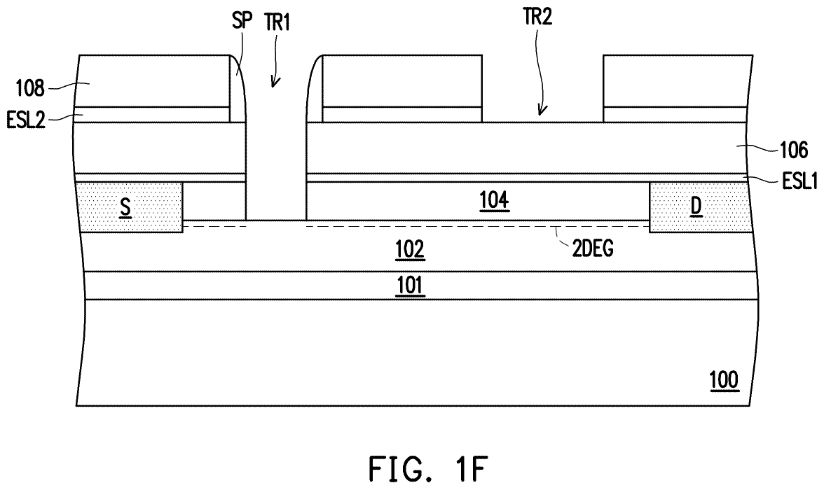

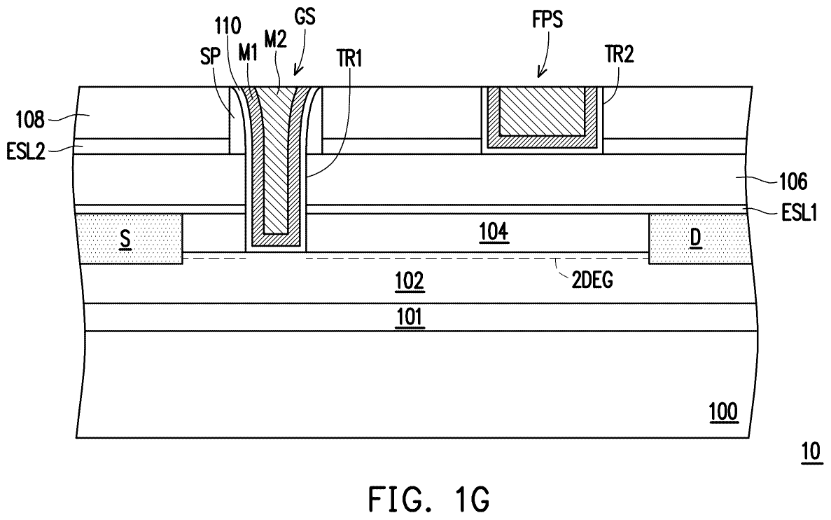

FIG. 1A to FIG. 1G are schematic cross-sectional views of a manufacturing process of a semiconductor power device according to a first embodiment of the disclosure.

The semiconductor power device in the embodiments of the disclosure includes a power transistor and a field plate electrically connected to the power transistor, and the process of the field plate structure including the field plate may be integrated with the process of the gate structure of the power transistor.

In addition, since the semiconductor power device in the embodiments of the disclosure includes multiple etching stop layers, additional photomasks and protective materials may not be needed in the manufacturing process of the semiconductor power device to form trenches with different depths for accommodating the gate structure and the field plate structure.

Additionally, in the manufacturing process of the semiconductor power device in the embodiments of the disclosure, a spacer is formed on the sidewall of the trench accommodating the gate structure. Therefore, the gate structure formed in the trench may have a smaller width, enabling the semiconductor power device in the embodiments of the disclosure to be applied under low operating voltages (for example, 5 V to 12 V).

In the following embodiments, a high-electron-mobility transistor (HEMT) is used as an example of the power transistor for explanation, but the disclosure is not limited thereto. The semiconductor power device and a manufacturing method thereof according to the embodiments of the disclosure will be described in detail below.

FIG. 1A to FIG. 1G are schematic cross-sectional views of a manufacturing process of a semiconductor power device according to a first embodiment of the disclosure.

First, referring to FIG. 1A, a substrate 100 is provided. The substrate 100 may be, for example, a silicon (Si) substrate, a silicon carbide (SiC) substrate, a gallium nitride (GaN) substrate, or a sapphire substrate. Following, a buffer layer 101 is formed on the substrate 100. A material of the buffer layer 101 may be, for example, AlGaN. The buffer layer 101 may have a superlattice structure. A thickness of the buffer layer 101 may be, for example, between 0.5 um and 6 um. In addition, in other embodiments, before forming the buffer layer 101, a nucleation layer may be formed on the substrate 100. A material of the nucleation layer may be, for example, AlN, GaN, or AlGaN. A thickness of the nucleation layer may be, for example, between 5 nm and 50 nm.

After forming the buffer layer 101, a nitride channel layer 102 is formed on the buffer layer 101. A material of the nitride channel layer 102 may be, for example, GaN or InGaN. A thickness of the nitride channel layer 102 may be, for example, between 0.2 um and 0.8 um. Then, a barrier layer 104 is formed on the nitride channel layer 102. A material of the barrier layer 104 may be, for example, AlGaN, InAlN, InAlGaN, or AlN. A thickness of the barrier layer 104 may be, for example, between 5 nm and 35 nm. After forming the barrier layer 104, a two-dimensional electron gas 2DEG is formed in the nitride channel layer 102, and the two-dimensional electron gas 2DEG is adjacent to an interface between the nitride channel layer 102 and the barrier layer 104.

After forming the barrier layer 104, a source S and a drain D are formed in the barrier layer 104 and the nitride channel layer 102. A material of the source S and the drain D may be, for example, silicon-doped GaN or silicon-doped InGaN, in which the concentration of silicon may be, for example, between 10×10¹⁹ cm⁻³ and 10×10²¹ cm⁻³.

In this embodiment, the method of forming the source S and the drain D may include the following steps. First, recesses are formed in the barrier layer 104 and the nitride channel layer 102 corresponding to the positions of the source and drain of the power transistor in the semiconductor power device. The bottom portions of the recesses are located in the nitride channel layer 102. Afterwards, an epitaxially growing process is performed to form the source S and the drain D in the recesses. In this embodiment, a top surface of the source S and a top surface of the drain D are coplanar with a plane of the barrier layer 104, but the disclosure is not limited thereto.

In this embodiment, since the source S and the drain D are formed in the barrier layer 104 and the nitride channel layer 102, the two-dimensional electron gas 2DEG is located between the source S and the drain D, and is continuous between the source S and the drain D.

Next, referring to FIG. 1B, a first etching stop layer ESL1, a first passivation layer 106, a second etching stop layer ESL2, a second passivation layer 108, and a third etching stop layer ESL3 are sequentially formed on the barrier layer 104 and the source S and the drain D.

In this embodiment, a thickness of the third etching stop layer ESL3 is greater than a thickness of the second etching stop layer ESL2, and the thickness of the second etching stop layer ESL2 is greater than a thickness of the first etching stop layer ESL1. A material of the first etching stop layer ESL1 may be, for example, AlN or Al₂O₃. A thickness of the first etching stop layer ESL1 may be, for example, between 1 nm and 2 nm. A material of the first passivation layer 106 may be, for example, AlN, Al₂O₃, SiO₂, or SiN. A thickness of the first passivation layer 106 may be, for example, between 0.05 nm and 30 nm. A material of the second etching stop layer ESL2 may be, for example, AlN or Al₂O₃. A thickness of the second etching stop layer ESL2 may be, for example, between 2 nm and 10 nm. A material of the second passivation layer 108 may be, for example, AlN, Al₂O₃, SiO₂, or SiN. A thickness of the second passivation layer 108 may be, for example, between 0.05 nm and 30 nm. A material of the third etching stop layer ESL3 may be, for example, AlN or Al₂O₃. A thickness of the third etching stop layer ESL3 may be, for example, between 5 nm and 20 nm.

Then, referring to FIG. 1C, a first trench TR1 is formed in the third etching stop layer ESL3, the second passivation layer 108, and the second etching stop layer ESL2. The first trench TR1 corresponds to the position of the gate structure of the power transistor in the semiconductor power device. The method of forming the first trench TR1 may include the following steps. First, a patterned photoresist layer is formed on the third etching stop layer ESL3. The patterned photoresist layer exposes the position corresponding to the gate structure of the power transistor in the semiconductor power device. Then, an etching process is performed to remove a portion of the third etching stop layer ESL3, a portion of the second passivation layer 108, and a portion of the second etching stop layer ESL2 until the first passivation layer 106 is exposed. Afterwards, the patterned photoresist layer is removed.

After forming the first trench TR1, a spacer SP is formed on the sidewall of the first trench TR1. A material of the spacer SP may be, for example, SiN, SiO₂, or SiON. A thickness of the spacer SP may be, for example, between 0.5 nm and 30 nm. The method of forming the spacer SP may include the following steps. First, a spacer material layer is conformally formed on the substrate 100. Afterwards, an anisotropic etching process is performed to remove a portion of the spacer material layer until a top surface of the third etching stop layer ESL3 and the first passivation layer 106 are exposed.

Based on the characteristics of the anisotropic etching process, a sidewall of an upper portion of the spacer SP may be convex, and a sidewall of middle and lower portions of the spacer SP may be substantially perpendicular to the plane of the substrate 100. Therefore, a width of the upper portion of the spacer SP may be smaller than a width of the middle and lower portions of the spacer SP.

In this embodiment, by forming the spacer SP in the first trench TR1, a width of the region used to accommodate the gate structure of the power transistor in the semiconductor power device may be reduced, and therefore it is advantageous for forming a gate structure with a smaller width.

Next, referring to FIG. 1D, a patterned mask layer 109 is formed on the third etching stop layer ESL3. The patterned mask layer 109 is located on the third etching stop layer ESL3 and fills the first trench TR1. In addition, the patterned mask layer 109 exposes the position corresponding to the field plate structure of the power transistor in the semiconductor power device. In this embodiment, the material of the patterned mask layer 109 is photoresist, but the disclosure is not limited thereto.

After forming the patterned mask layer 109, an anisotropic etching process is performed using the patterned mask layer 109 as an etching mask to remove a portion of the third etching stop layer ESL3 and form a second trench TR2 in the third etching stop layer ESL3. The second trench TR2 exposes the second passivation layer 108.

Then, referring to FIG. 1E, the patterned mask layer 109 is removed. Next, an anisotropic etching process is performed using the third etching stop layer ESL3 and the spacer SP as an etching mask. In the anisotropic etching process, the first passivation layer 106, the first etching stop layer ESL1, and the barrier layer 104 below the first trench TR1 are removed, enabling the first trench TR1 to extend downward through the first passivation layer 106, the first etching stop layer ESL1, and the barrier layer 104 to expose the nitride channel layer 102. In addition, in the anisotropic etching process, the second passivation layer 108 below the second trench TR2 is also simultaneously removed, enabling the second trench TR2 to extend downward through the second passivation layer 108 to expose the second etching stop layer ESL2.

In this embodiment, since the thickness of the third etching stop layer ESL3 is greater than the thickness of the second etching stop layer ESL2, and the thickness of the second etching stop layer ESL2 is greater than the thickness of the first etching stop layer ESL1, during the above-mentioned anisotropic etching process, the third etching stop layer ESL3 and the second etching stop layer ESL2 below the second trench TR1 will not be completely removed. In other words, in this embodiment, by adjusting the thickness of the first etching stop layer ESL1, the thickness of the second etching stop layer ESL2, and the thickness of the third etching stop layer ESL3, the first trench TR1 and the second trench TR2 with different depths may be formed in the same etching process. In addition, during the above-mentioned anisotropic etching process, the upper portion of the spacer SP may also be slightly removed.

In addition, in the step described in FIG. 1E, since the first trench TR1 extends downward to expose the nitride channel layer 102, the two-dimensional electron gas 2DEG will not exist directly below the first trench TR1.

Next, referring to FIG. 1F, the third etching stop layer ESL3 on the second passivation layer 108 and the second etching stop layer ESL2 exposed by the second trench TR2 are removed. The method for removing the third etching stop layer ESL3 and the second etching stop layer ESL2 may be performed by a wet etching process. In addition, in this embodiment, during the process of removing the third etching stop layer ESL3 and the second etching stop layer ESL2 by the wet etching process, the upper portion of the spacer SP may also be slightly removed.

Afterwards, referring to FIG. 1G, a gate structure GS is formed in the first trench TR1, and a field plate structure FPS is formed in the second trench TR2. In this embodiment, the method for forming the gate structure GS and the field plate structure FPS may include the following steps. First, a high dielectric constant dielectric layer 110 is conformally formed on the substrate 100. In this technical field, a high dielectric constant usually refers to a dielectric constant greater than 4. In this embodiment, a material of the dielectric layer 110 may be HfO, Al₂O₃ or AlN. A thickness of the dielectric layer 110 may be between 0.05 nm and 30 nm. Next, a conductive layer M1 is conformally formed on the dielectric layer 110. A material of the conductive layer M1 may be TiN, Ni, Ti, AlCu, Al or AlSi. A thickness of the conductive layer M1 may be between 0.05 nm and 30 nm. The method for forming the conductive layer M1 may be performed by an atomic layer deposition process. Then, a conductive layer M2 is formed on the conductive layer M1 to fill the first trench TR1 and the second trench TR2. A material of the conductive layer M2 may be W or Cu. The method for forming the conductive layer M2 may be performed by a chemical vapor deposition process. Afterwards, the dielectric layer 110, the conductive layer M1, and the conductive layer M2 outside the first trench TR1 and the second trench TR2 are removed. The method for removing the dielectric layer 110, the conductive layer M1, and the conductive layer M2 outside the first trench TR1 and the second trench TR2 may be performed by a chemical mechanical polishing (CMP) process or an etching-back process.

After removing the dielectric layer 110, the conductive layer M1, and the conductive layer M2 outside the first trench TR1 and the second trench TR2, the dielectric layer 110, the conductive layer M1, and the conductive layer M2 in the first trench TR1 constitute the gate structure GS, while the dielectric layer 110, the conductive layer M1, and the conductive layer M2 in the second trench TR2 constitute the field plate structure FPS. That is to say, in this embodiment, the gate structure GS and the field plate structure FPS may be constituted from the same material, and may be formed in the same process step.

In the gate structure GS, the dielectric layer 110 serves as a gate dielectric layer, while the conductive layer M1 and the conductive layer M2 together serve as the gate. In the field plate structure FPS, the conductive layer M1 and the conductive layer M2 together serve as the field plate. As a result, a semiconductor power device 10 of this embodiment including the power transistor and the field plate structure is formed.

In the semiconductor power device 10, the buffer layer 101 and the nitride channel layer 102 are sequentially disposed on the substrate 100, the source S and the drain D are disposed on the nitride channel layer 102, and the barrier layer 104 is disposed on the nitride channel layer 102 between the source S and the drain D. In addition, the first etching stop layer ESL1, the first passivation layer 106, the second etching stop layer ESL2, and the second passivation layer 108 are sequentially disposed on the barrier layer 104 and the source S and the drain D.

The gate structure GS is disposed in the second passivation layer 108, the second etching stop layer ESL2, the first passivation layer 106, the first etching stop layer ESL1, and the barrier layer 104, enabling the two-dimensional electron gas 2DEG to be located in the nitride channel layer 102 between the source S and the drain D, adjacent to the interface between the nitride channel layer 102 and the barrier layer 104, and not existing below the gate structure GS. Therefore, the power transistor in the semiconductor power device 10 is an enhancement-mode (E-mode) power transistor.

The spacer SP is disposed between the gate structure GS and the second passivation layer 108 and the second etching stop layer ESL2. In this embodiment, since the width of the upper portion of the spacer SP is smaller than the width of the middle and lower portions of the spacer SP, the width of the top portion of the gate structure GS is greater than the width of the bottom portion of the gate structure GS.

The field plate structure FPS is disposed in the second passivation layer 108 and the second etching stop layer ESL2, and may be electrically connected to the gate structure GS through a conductive element formed in a subsequent process.

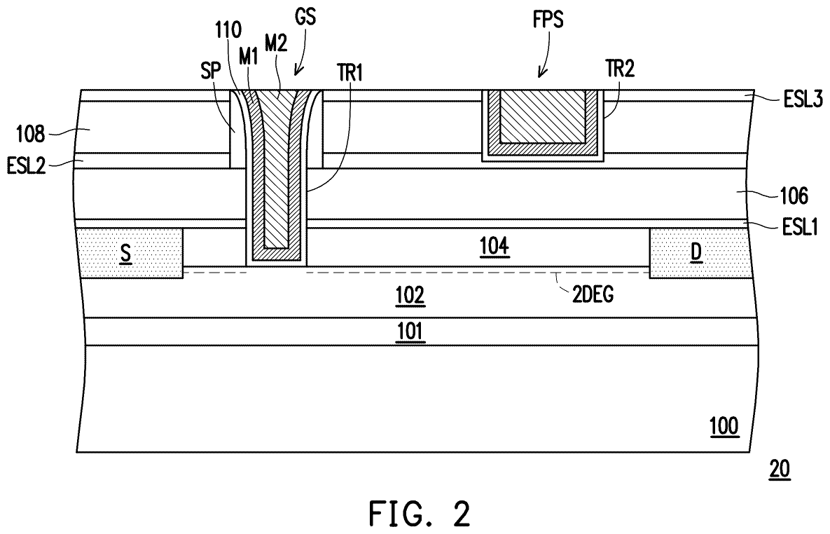

FIG. 2 is a schematic cross-sectional view of a semiconductor power device according to a second embodiment of the disclosure. In this embodiment, the same elements as those in the first embodiment will be denoted by the same reference symbols, and related details will not be described again.

Referring to FIG. 2, the difference between a semiconductor power device 20 of this embodiment and the semiconductor power device 10 of the first embodiment lies in that: in the semiconductor power device 20, the field plate structure FPS is formed in the third etching stop layer ESL3, the second passivation layer 108, and the second etching stop layer ESL2, and the bottom portion of the field plate structure FPS is located in the second etching stop layer ESL2.

In detail, after performing the steps described in FIG. 1A to FIG. 1E, the step described in FIG. 1F is not performed, so as to retain the third etching stop layer ESL3 on the second passivation layer 108, and to retain the second etching stop layer ESL2 below the second trench TR2. In this way, the process steps of the semiconductor power device 20 may be further simplified.

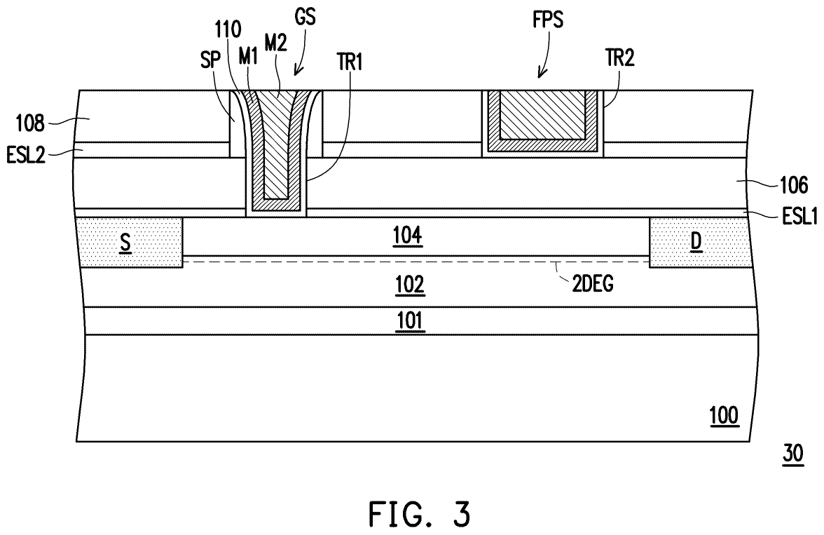

FIG. 3 is a schematic cross-sectional view of a semiconductor power device according to a third embodiment of the disclosure. In this embodiment, the same elements as those in the first embodiment will be denoted by the same reference symbols, and related details will not be described again.

Referring to FIG. 3, the difference between a semiconductor power device 30 of this embodiment and the semiconductor power device 10 of the first embodiment lies in that: in the semiconductor power device 30, the gate structure GS is formed in the second passivation layer 108, the second etching stop layer ESL2, the first passivation layer 106, and the first etching stop layer ESL1, and does not extend downward into the barrier layer 104. Since the barrier layer 104 exists between the gate structure GS and the nitride channel layer 102, the two-dimensional electron gas 2DEG is continuous between the source S and the drain D. Therefore, the power transistor in the semiconductor power device 30 is a depletion-mode (D-mode) power transistor. In addition, the field plate structure FPS is formed in the second passivation layer 108 and the second etching stop layer ESL2, and the bottom portion of the field plate structure FPS is located on the first passivation layer 106.

In detail, after performing the steps described in FIG. 1A to FIG. 1D, in the step described in FIG. 1E, the first trench TR1 is only extended downward through the first passivation layer 106 to expose the first etching stop layer ESL1, and the second trench TR2 is extended downward through the second passivation layer 108 to expose the second etching stop layer ESL2. In addition, in the step described in FIG. 1F, in addition to removing the third etching stop layer ESL3 on the second passivation layer 108 and the second etching stop layer ESL2 exposed by the second trench TR2, the first etching stop layer ESL1 exposed by the first trench TR1 is also removed.

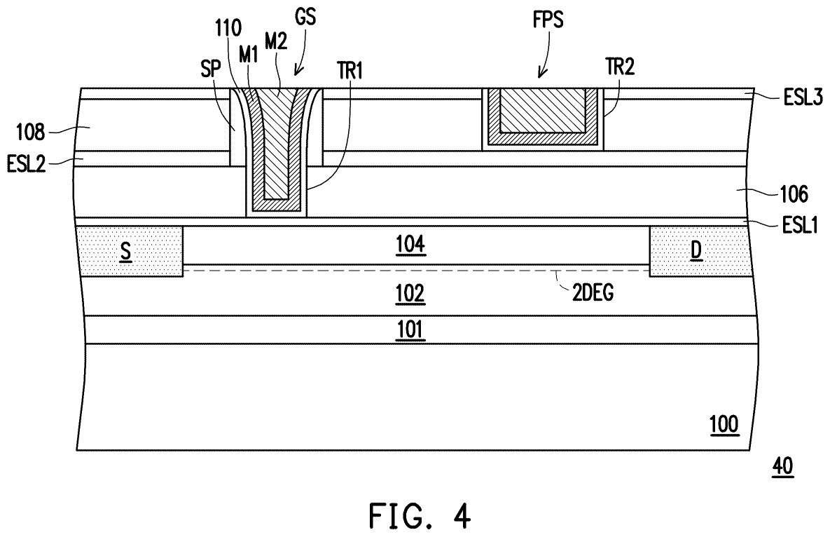

FIG. 4 is a schematic cross-sectional view of a semiconductor power device according to a fourth embodiment of the disclosure. In this embodiment, the same elements as those in the first embodiment will be denoted by the same reference symbols, and related details will not be described again.

Referring to FIG. 4, the difference between a semiconductor power device 40 of this embodiment and the semiconductor power device 10 of the first embodiment lies in that: in the semiconductor power device 40, the gate structure GS is formed in the third etching stop layer ESL3, the second passivation layer 108, the second etching stop layer ESL2, and the first passivation layer 106, and does not extend downward into the first etching stop layer ESL1 and the barrier layer 104. Since the barrier layer 104 exists between the gate structure GS and the nitride channel layer 102, the two-dimensional electron gas 2DEG is continuous between the source S and the drain D. Therefore, the power transistor in the semiconductor power device 40 is a D-mode power transistor. In addition, the field plate structure FPS is formed in the third etching stop layer ESL3 and the second passivation layer 108, and the bottom portion of the field plate structure FPS is located on the second etching stop layer ESL2.

In detail, after performing the steps described in FIG. 1A to FIG. 1D, in the step described in FIG. 1E, the first trench TR1 is only extended downward through the first passivation layer 106 to expose the first etching stop layer ESL1, and the second trench TR2 is extended downward through the second passivation layer 108 to expose the second etching stop layer ESL2. In addition, after the step described in FIG. 1E, the step described in FIG. 1F is not performed, so as to retain the third etching stop layer ESL3 on the second passivation layer 108, the first etching stop layer ESL1 below the first trench TR1, and the second etching stop layer ESL2 below the second trench TR2.

In the above embodiments, after forming the semiconductor power device, subsequent well-known processes may be performed. For example, after forming the semiconductor power device, contacts that form ohmic contact with the source S and the drain D respectively, contacts electrically connected to the gate structure GS, and contacts electrically connected to the field plate structure FPS may be formed.

Although the disclosure has been described with reference to the embodiments above, the embodiments are not intended to limit the disclosure. Any person skilled in the art can make some changes and modifications without departing from the spirit and scope of the disclosure. Therefore, the scope of the disclosure will be defined in the appended claims.

What is claimed is:

1. A semiconductor power device, comprising:
a substrate;
a buffer layer, disposed on the substrate;
a nitride channel layer, disposed on the buffer layer;
a source and a drain, disposed on the nitride channel layer;
a barrier layer, disposed on the nitride channel layer between the source and the drain;
a first etching stop layer, disposed on the barrier layer and the source and the drain;
a first passivation layer, disposed on the first etching stop layer;
a second etching stop layer, disposed on the first passivation layer;
a second passivation layer, disposed on the second etching stop layer;
a gate structure, disposed in the second passivation layer, the second etching stop layer, and the first passivation layer;
a spacer, disposed between the gate structure and the second passivation layer and the second etching stop layer; and
a field plate structure, disposed in the second passivation layer,
wherein a two-dimensional electron gas is located in the nitride channel layer between the source and the drain, and is adjacent to an interface between the nitride channel layer and the barrier layer.

2. The semiconductor power device according to claim 1, wherein a thickness of the second etching stop layer is greater than a thickness of the first etching stop layer.

3. The semiconductor power device according to claim 1, wherein the gate structure further extends through the barrier layer.

4. The semiconductor power device according to claim 3, wherein the two-dimensional electron gas does not exist below the gate structure.

5. The semiconductor power device according to claim 1, wherein the field plate structure further extends through the second etching stop layer.

6. The semiconductor power device according to claim 1, further comprising a third etching stop layer, disposed on the second passivation layer, wherein the gate structure and the field plate structure further extend through the third etching stop layer.

7. The semiconductor power device according to claim 6, wherein a thickness of the third etching stop layer is greater than a thickness of the second etching stop layer.

8. The semiconductor power device according to claim 6, wherein a bottom portion of the field plate structure is located on the second etching stop layer.

9. The semiconductor power device according to claim 1, wherein the gate structure comprises:
a first conductive layer;
a dielectric layer, disposed on a sidewall and a bottom surface of the first conductive layer; and
a second conductive layer, disposed between the first conductive layer and the dielectric layer.

10. The semiconductor power device according to claim 9, wherein the field plate structure comprises:
the first conductive layer;
the dielectric layer, disposed on the sidewall and the bottom surface of the first conductive layer; and
the second conductive layer, disposed between the first conductive layer and the dielectric layer.

11. The semiconductor power device according to claim 1, wherein a width of a top portion of the gate structure is greater than a width of a bottom portion of the gate structure.

12. A manufacturing method of a semiconductor power device, comprising:
forming a buffer layer on a substrate;
forming a nitride channel layer on the buffer layer;
forming a source and a drain on the nitride channel layer;
forming a barrier layer on the nitride channel layer between the source and the drain;
forming a first etching stop layer on the barrier layer and the source and the drain;
forming a first passivation layer on the first etching stop layer;
forming a second etching stop layer on the first passivation layer;
forming a second passivation layer on the second etching stop layer;
forming a gate structure in the second passivation layer, the second etching stop layer, and the first passivation layer;
forming a spacer between the gate structure and the second passivation layer and the second etching stop layer; and
forming a field plate structure in the second passivation layer,
wherein a two-dimensional electron gas is located in the nitride channel layer between the source and the drain, and is adjacent to an interface between the nitride channel layer and the barrier layer.

13. The manufacturing method of the semiconductor power device according to claim 12, wherein the gate structure comprises:
a first conductive layer;
a dielectric layer, disposed on a sidewall and a bottom surface of the first conductive layer; and
a second conductive layer, disposed between the first conductive layer and the dielectric layer.

14. The manufacturing method of the semiconductor power device according to claim 13, wherein the field plate structure comprises:
the first conductive layer;
the dielectric layer, disposed on the sidewall and the bottom surface of the first conductive layer; and
the second conductive layer, disposed between the first conductive layer and the dielectric layer.

15. The manufacturing method of the semiconductor power device according to claim 14, wherein the method of forming the gate structure, the spacer, and the field plate structure comprises:
after forming the second passivation layer, forming a third etching stop layer on the second passivation layer;
performing a first etching process to form a first trench in the third etching stop layer, the second passivation layer, and the second etching stop layer;
forming the spacer on a sidewall of the first trench;
performing a second etching process to form a second trench in the third etching stop layer;
performing a third etching process to extend the first trench downward through the first passivation layer, and to extend the second trench downward through the second passivation layer, wherein the first trench exposes the first etching stop layer, and the second trench exposes the second etching stop layer; and
sequentially forming the dielectric layer, the second conductive layer, and the first conductive layer in the first trench and the second trench.

16. The manufacturing method of the semiconductor power device according to claim 15, further comprising removing the third etching stop layer, the first etching stop layer exposed by the first trench, and the second etching stop layer exposed by the second trench after performing the third etching process and before forming the dielectric layer.

17. The manufacturing method of the semiconductor power device according to claim 15, wherein a thickness of the third etching stop layer is greater than a thickness of the second etching stop layer, and the thickness of the second etching stop layer is greater than a thickness of the first etching stop layer.

18. The manufacturing method of the semiconductor power device according to claim 13, wherein the method of forming the first conductive layer comprises performing a chemical vapor deposition process.

19. The manufacturing method of the semiconductor power device according to claim 13, wherein the method of forming the second conductive layer comprises performing an atomic layer deposition process.

20. The manufacturing method of the semiconductor power device according to claim 12, wherein a width of a top portion of the gate structure is greater than a width of a bottom portion of the gate structure.
